(19) United States
(12) Patent Application Publication
(10) Pub. No.: US 2012/0326278 A1
(43) Pub. Date: Dec. 27, 2012

(54) METHOD TO SOLVE POTENTIAL YIELD LOSS DUE TO METAL MIGRATION TO WIRE ROUTING NETS FROM FIDUCIARY MARKS ON PRODUCT DURING CHEMICAL-MECHANICAL-POLISHING (CMP) PLANARIZATION PROCESSING STEPS

(75) Inventors: OSCAR JOSEPH SALDANHA, Fremont, CA (US); PEKKA KALERVO OJALA, Fremont, CA (US); DAVID RICHARD MOOG, San Jose, CA (US)

(73) Assignee: EXAR CORPORATION, Fremont, CA (US)

(21) Appl. No.: 13/167,603

(22) Filed: Jun. 23, 2011

(51) Int. Cl. H01L 23/544; G06F 17/50; B32B 3/00; H01L 21/71

(52) U.S. Cl. 257/618; 438/401; 716/55; 428/195.1; 257/E23.179; 257/E21.536

(57) ABSTRACT

A mask for a semiconductor process step includes an indicia section. The indicia section on the mask is used to produce a field of separated polygon elements with a defined negative space in the field providing an indicia.

### FIELD OF THE INVENTION

The present invention relates the forming of indicia on semiconductor chips and masks used to form semiconductor chips.

### BACKGROUND

Semiconductor chips often use indicia, such as identifying indicia or fiduciary marks, to identify the chip. The identifying indicia can include company names, company logos or the like. Such indicia are put on the semiconductor masks used to form layers of the semiconductor chip. The indicia can provide benefits under the United States semiconductor mask work law that allow for notice including the symbol “M” and an identification of the owners of the rights of a mask work.

As the size of the processes get smaller, the fabrication design requirements for the identifying indicia become more stringent. For example, Chemical-Mechanical-Polishing (CMP) steps put restrictions on the design such as requiring densities above a minimum value. Traditional indicias have a relatively low density. Further, in metallization layers, the traditional indicia also have relatively large connected metal regions or co-incident metal edges on separate metallization layers that can, in some cases, form cracks or allow metallization fragments become free in a CMP step and interfere with other parts of the chip.

### SUMMARY

Embodiments of the present invention use a mask with an indicia section having a field of separated polygon elements with a defined negative space providing the indicia. These separated polygon shapes can be automatically generated fill shapes. The mask forms such an indicia onto a layer of the semiconductor chip.

The new design avoids low density problems of the prior solutions. When the mask is used for a metallization layer, such a design also avoids the creation of large connected metal regions that may provide problems with CMP processes.

### BRIEF DESCRIPTION OF THE DRAWINGS

FIGS. 1 and 2 show examples of prior art indicia for semiconductor chips and masks.

FIGS. 3 and 4 show the indicia of an embodiment of the present invention.

### DETAILED DESCRIPTION

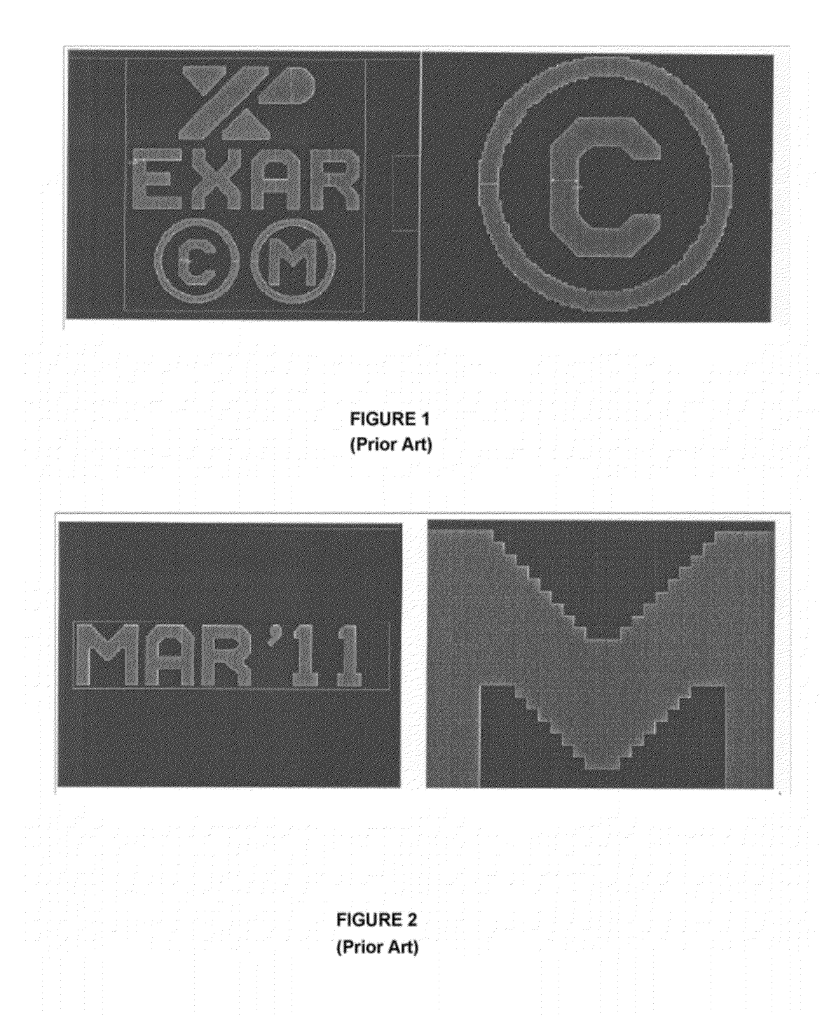

FIGS. 1 and 2 shows an example of prior art indicia for semiconductor chips and masks.

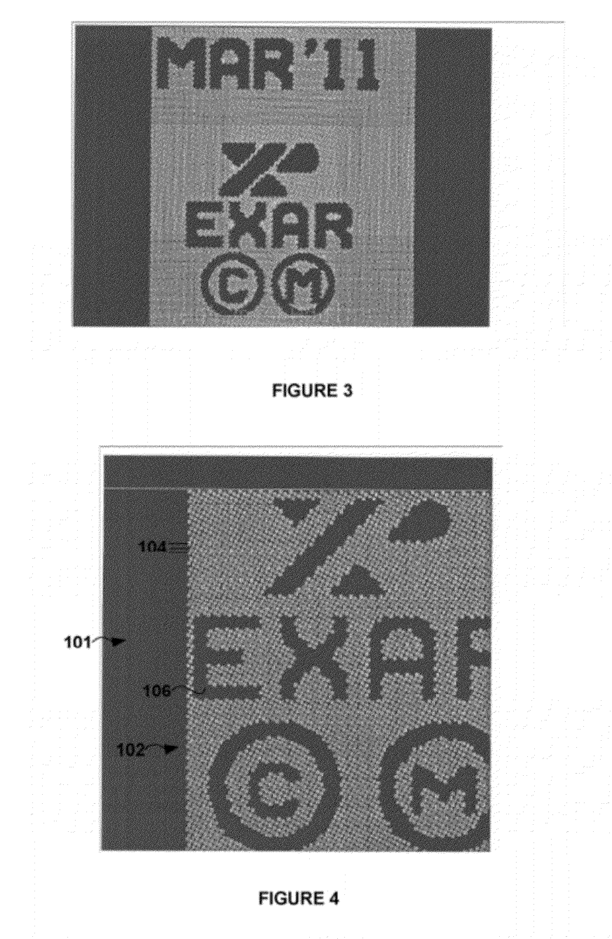

FIGS. 3 and 4 show indicia of embodiments of the present invention with FIG. 4 showing a detail of FIG. 3.

FIG. 4 shows a detail of a mask 101 for a semiconductor process step. An indicia section 102 is shown. The indicia section 102 on the mask is used to produce a field of separated polygon elements 104 with a defined negative space 106 in the separated polygon elements providing an indicia. The defined polygon elements 104 can be rectangular, such as square shaped, or have different sized edges. The polygon shapes can have orthogonal angles or have non-orthogonal, design rule compliant angles between adjacent edges. The defined polygon elements 104 can be automatically generated fill shapes.

The produced separated polygon elements are drawn to satisfy design rules for minimum feature dimension or space from the closest neighbor polygon element

The mask can be for a metallization layer, polysilicon layer or other layer.

The indicia is viewable using a microscope to identify the mask and chips.

The mask is used to form a chip with an indicia section including a field of separated polygon elements in a layer with a defined negative space in the separated polygon elements providing an indicia. Another indicia section with another field of separated polygon elements for another layer from another mask can be at the same or another location on the chip.

The present invention improves chip or die yield by:
1. Reducing or eliminating potential chemical-mechanical-polishing (CMP) related un-evenness of surfaces or “dishing” effects caused by the presence of indicia, such as fiduciary marks and
2. Providing a near planar topographical surface in the presence of indicia or fiduciary marks thereby facilitating uniform removal of unwanted residues generated in the CMP process and
3. Reducing a probability of carrying wide text label and logo area metallization material to dense wiring area by CMP process module, which is proven to cause unintended connections or “shorting” between the routing level wires that are meant to be electrically isolated nets.

With shrinking technologies, planarization requirements are getting more stringent so that feature line-widths can be drawn with negligible variation on the die in the face of tight depth to focus requirements of the optical system.

Indicias or fiducials (fiduciary marks) on the die are typically used for die alignment marks or for establishing Company-proprietary identifying marks, logos and dates.

These marks traditionally use drawn alphabets, alpha-numeric's characters or even symbols, in a language of user's choice and must be visually or machine identifiable on masks, reticles and on different layers on the dies.

However, in order to avoid circuit level failures, the drawing of these marks needs to also conform to the design-rule for the particular submicron technology. The manufacturing limitations imposed by the design-rules are typically (and not limited to):
1. Width of shapes (used to create the mark) and possibly required slotting for wide structures
2. Spacing between shapes
3. Limited allowed orientation (horizontal, vertical, 45 degrees, etc.) that can be used to draw the shape
4. Limited allowed co-incident metal level edges above certain length.

Certain fabrication design rules do allow for the masking of design rule violations over user created indicias or fiduciary marks. However, the mere presence of the indicia or fiduciary marks, as drawn, still poses a yield problem as stated above.

The proposed method:
1. Eliminates the difficulties encountered in the creation of such shapes for indicia or fiduciary purposes while still allowing for the identification of these marks on masks, reticles or on the layers of the dies.
2. Addresses the chip or die yield issues alluded to above.

This method eliminates the requirement to create design rule compliant drawn shapes for generation of indicia or fiduciary marks. Therefore, it eases the creation of identifiable indicia or fiduciary marks while simultaneously improving on the chip or die yield requirements as stated above.

The fabrication design rules require a topographically uniform layout for efficient planarization of layers on the die. The density-check routine in the design rules checker will flag non-uniform density areas that could potentially and adversely impact planarization during the CMP process. These areas can be filled in with design rule approved shapes (“fill-shapes”).

The “fill-shapes” are arrayed to fill the areas that are deficient in meeting the density requirements. The patterning in the array of “fill-shapes” does meet the mandated design-rule requirements stipulated by the Fabrication House.

The proposed method uses these arrays of fabrication design rule layer fill shapes to generate the outlines of the indicia or fiduciary marks.

The proposed method focuses on adhering to the planarization requirements by the Fabrication Design Rules.

It employs the selective removal of fill-shapes to reveal and contrast the intended indicia or fiduciary marks for legibility as an open area without fill-shapes forming the desired lettering or pattern.

Since “fill-shapes” are typically much smaller than the drawing shapes used in indicia or fiduciary mark creation, this proposed method maintains high planarization and uniform topography of the areas around the indicia or fiduciary marks and allows easy detection of intended characters and patterns.

By selective removal of “fill-shapes”, there is no extra effort entailed to comply with the difficult Fabrication Design Rule requirements associated with the generation of indicia or fiduciary marks.

The previous method of having to commit to draw indicia or fiduciary marks is hereby eliminated in the proposed method. As technology shrinks the difficulty in the generation of Design Rule compliant indicia or fiduciary shapes as exercised in the previous art cannot be understated.

As stated above, the large shapes of the indicia or fiduciary mark are counter productive in enhancing chip or die yields (thereby leading to wasted dies and lowering yields). The proposed method, on the other hand, uses selective removal of smaller “fill-shapes”, instead, that:
1. Allows easy identification marks by enhancing contrast through “absence” of “fill-shapes” to outline marks.
2. Allow flexibility in generation of outlines of indicia or fiduciary marks (alphabets, alpha-numeric's and symbols or patterns that can be used) within the fill-shapes resolution and placement without directional restrictions.
3. Present no Design Rule violation overhead to be reckoned with in generation of indicia or fiduciary marks.
4. Fill shapes automatically comply to the foundry design rules by generation algorithm.
5. Optical Proximity Correction (OPC) does not have to be used on fill-shapes which provides easier generation of mask-layers using the shapes from drawn data.
6. Enhances yields by enforcing planarization and Chemical-Mechanical-Polishing (CMP) required design rules.
7. Reduces probability of shorts in metal routing wires due to metallization levels material transfer from large area indicia or fiduciary marks by CMP.

The foregoing description of preferred embodiments of the present invention has been provided for the purposes of illustration and description. It is not intended to be exhaustive or to limit the invention to the precise forms disclosed. Many embodiments were chosen and described in order to best explain the principles of the invention and its practical application, thereby enabling others skilled in the art to understand the invention for various embodiments and with various modifications that are suited to the particular use contemplated. It is intended that the scope of the invention be defined by the claims and their equivalents.

1. A mask for a semiconductor process step including:
an indicia section, the indicia section on the mask used to produce a field of separated polygon elements with a defined negative space in the field providing an indicia.

2. The mask of claim 1, wherein the defined polygon elements are design-rule compliant.

3. The mask of claim 1, wherein the produced separated polygon elements are equal or more than minimum design rule along the edges.

4. The mask of claim 3, wherein the produced separated polygon elements are separated by minimum design rule or more from a closest neighbor polygon element.

5. The mask of claim 1, wherein the mask is for a metallization layer.

6. The mask of claim 1, wherein the indicia are viewable using a microscope.

7. The mask of claim 1, wherein the separated polygon elements are fill shapes.

8. A chip including:
an indicia section including a field of separated polygon elements in a layer with a defined negative space in the separated polygon elements providing an indicia.

9. The chip of claim 8, wherein the defined polygon elements are design-rule compliant.

10. The chip of claim 8, wherein the produced separated polygon elements are equal or more than minimum design rule along the edges.

11. The chip of claim 10, wherein the produced separated polygon elements are separated by minimum design rule or more from a closest neighbor polygon element.

12. The chip of claim 8, wherein the indicia are viewable using a microscope.

13. The chip of claim 8, wherein the indicia section of the layer is defined by a mask for the layer.

14. The chip of claim 13, wherein the layer is a metallization layer.

15. The chip of claim 8, wherein another indicia section with another field of separated polygon elements for another layer made by another mask is at another location of the chip.

16. The chip of claim 8, wherein the separated polygon elements are fill shapes.

17. A method of forming a semiconductor chip comprising:
using a mask to form a layer, the mask including an indicia section, the section on the mask used to produce a field of separated polygon elements with a defined negative space in the separated polygon elements providing an indicia.

18. The method of claim 17, wherein the defined polygon elements are design-rule compliant.

19. The method of claim 17, wherein the produced separated polygon elements are equal or more than minimum design rule along the edges.

20. The method of claim 19, wherein the produced separated polygon elements are separated by minimum design rule or more from a closest neighbor polygon element.

21. The method of claim 17, wherein the mask is for a metallization layer.

22. The method of claim 17, wherein the indicia is human viewable using a microscope.

23. The method of claim 17, wherein the separated polygon elements are fill shapes.

24. The method of claim 23, wherein the fill shapes are automatically generated.

25. A method comprising:
automatically generating fill shapes for a section of a mask; and
removing some of the fill shapes to form a indicia in the mask, the indicia being formed in negative space within the automatically generated fill shapes.

26. The method of claim 25, wherein the automatically generated fill shapes are polygon shaped.

27. The method of claim 25, wherein the automatically generated fill shapes have orthogonal angles.

28. The method of claim 25, wherein the automatically generated fill shapes have design rule compliant angles and wherein at least one of the design rule compliant angles is non-orthogonal.
